(19) United States
(12) Patent Application Publication
(10) Pub. No.: US 2015/0279451 A1
(43) Pub. Date: Oct. 1, 2015

(54) EDGE-TRIGGERED PULSE LATCH

(71) Applicant: QUALCOMM Incorporated, San Diego, CA (US)

(72) Inventors: Chulmin Jung, San Diego, CA (US); Wuyang Hao, Santa Clara, CA (US); Sei Seung Yoon, San Diego, CA (US)

(73) Assignee: QUALCOMM Incorporated, San Diego, CA (US)

(21) Appl. No.: 14/227,330

(22) Filed: Mar. 27, 2014

(51) Int. Cl. G11C 11/418

(52) U.S. Cl. CPC G11C 11/418

(57) ABSTRACT

A pulse latch is provided that latches a ground signal responsive to decoded signal carried on a decoded signal node. The pulse latch includes a reset logic circuit that controls a switch coupled between the decoded signal node and ground such that when the switch is turned on by the reset logic circuit, the decoded signal node is grounded. The reset of the decoded signal node by the reset logic circuit is responsive to a ground signal. The ground signal is generated so as to be responsive to a clock edge. Thus, the reset of the decoded signal node is also responsive to the clock edge.

### TECHNICAL FIELD

This application relates to a pulse latch, and more particularly to an edge-triggered pulse latch.

### BACKGROUND

In conventional memory operation, an address decoder decodes an address so as to assert the appropriate word line in the memory to a power supply voltage. Unselected word lines are maintained at ground. Address decoders for memories such as SRAM caches conventionally perform the word line assertion and de-assertion using a pulse latch. An example conventional pulse latch 100 is shown in FIG. 1. In pulse latch 100, there are three address bits A0, A1, and A2 being decoded through a NAND gate 105. An output from NAND gate 105 drives an inverter 110 that inverts the NAND output into a DEC signal. A global reset signal drives a gate of an NMOS transistor M1 coupled between a DEC signal node 111 carrying the DEC signal and ground. The DEC signal drives a gate of an NMOS transistor M2 whose source is coupled to a VSSG signal and whose drain 112 is coupled to an input of an inverter 115 that is cross-coupled with another inverter 120 to form the storage unit in pulse latch 100. The drain voltage for transistor M2 that is latched in pulse latch 100 may be designated as a latched Q signal. An inverter 125 inverts the latched Q signal to drive a word line (not illustrated). Thus, when the latched Q signal is pulled low to ground, the word line voltage is driven high to a power supply voltage VDD2.

The word line couples to a delay circuit (not illustrated) that generates a feedback signal that drives a gate of a PMOS transistor P1 coupled between a power supply node providing the power supply voltage VDD2 and drain 112 of transistor M2. The feedback signal is the complement of the word line voltage. Thus, when the word line voltage goes high, the feedback signal will eventually go low, which turns on transistor P1 to charge the latched Q signal high, which then causes the word line voltage to be pulled low.

The latched Q signal will thus be momentarily low to drive the word line voltage high. After being momentarily low, the latched Q signal is pulled high, which pulls the word line voltage low. In this fashion, pulse latch 100 operates to pulse the word line voltage for a sufficient duration so that the corresponding memory cell(s) coupled to the asserted word line may be accessed in a read or write operation. As compared to the VDD2 voltage domain for the word line assertion, the DEC signal generation may occur in a lower voltage domain corresponding to a power supply voltage VDD1. A PMOS transistor P2 couples between a power supply terminal for inverter 110 and a power supply node providing the power supply voltage VDD1. The global reset signal drives the gate of transistor P2 such that when the global reset signal is low, inverter 110 is powered so that it may drive the DEC signal high in response to the address bits all being high.

A memory clock signal controls the VSSG signal (which may also be denoted as a ground signal) so that the VSSG signal is pulled low in response to the memory clock signal going high. The address signals must thus be stable prior to the rising edge of the memory clock. In other words, an address generation circuit (not illustrated) generates the address signals such as A0, A1, A2 so the address signals may be processed through NAND gate 105 and inverter 110 to generate the DEC signal (whether it is to be low or high) prior to the rising edge of the memory clock. For example, if the address signals A0, A1, and A2 are all asserted prior to the rising edge of the memory clock, then the DEC signal will be asserted high prior to the VSSG signal being pulled low. In this fashion, the resulting low state for the VSSG signal may pull the latched Q signal low through transistor M2. Similarly, if the address signals are generated such that one or more of them are low prior to the rising edge of the memory clock, then the DEC signal will be low prior to VSSG being pulled low. The resulting low state for the VSSG signal will then have no effect on the latched Q signal because transistor M2 will be turned off.

The timing of the DEC signal may be better appreciated with reference to the timing diagram of FIG. 2. The VSSG signal goes low to ground in response to a rising edge in the memory clock signal (elk). But the DEC signal was already setup (either high or low) prior to the rising edge of the memory clock as it takes some time for DEC to be stable in the processing though NAND gate 105 and inverter 110. The latched Q signal (not illustrated in FIG. 2) will then be either pulled low (if the DEC signal is high) or maintained high (if the DEC signal is low).

The DEC signal may thus either be low or high prior to the VSSG signal being pulled low. After the rising edge of the memory clock, the address signals will eventually need to change state to correspond to whatever value they will have in the subsequent memory clock cycle. So it could be that the DEC signal was low prior to the rising edge of a current memory clock cycle but will go high sometime after the rising edge in the current memory clock cycle. In such a case, the latched Q signal could be driven low undesirably. Referring again to FIG. 1, a global reset generation circuit (not illustrated) asserts the global reset signal in response to detecting that a “dummy latched Q signal” has gone low. The global reset generation circuit (not illustrated) includes a tracking circuit that models the assertion of the DEC signal followed by the VSSG signal going low so as to pull the latched Q signal low. In other words, the global reset generation circuit generates the dummy latched Q signal as if the DEC signal were high prior to every rising edge of the clock. The global reset generation circuit detects when the dummy latched Q signal has been pulled low and drives the global reset signal high accordingly.

The asserted global reset signal then turns on transistor M1 to pull the DEC signal low to ground. This low state for the DEC signal then protects the latched Q signal from changing after the address signals are released so as to change state in preparation for the subsequent memory clock cycle because transistor M2 is turned off in response to the low state of the DEC signal. As shown in FIG. 2, the DEC signal must be maintained in its state (high or low) for a sufficient duration after the assertion of the global reset signal. The holding of the DEC signal beginning prior to the rising edge of the memory clock and continuing after the assertion of the global reset signal lowers the achievable memory speed because the holding time of the DEC signal must account for the delay for the global reset generation circuit to detect that its dummy latched Q signal has gone low.

Accordingly, there is a need in the art for faster pulse latch operation.

### SUMMARY

A pulse latch is provided that includes a decoding circuit configured to decode address signals to control an assertion of a decoded signal on a decoded signal node. The decoded signal controls a first switch to couple a ground signal to a latch if the decoded signal is asserted. The ground signal is generated by a ground signal generator that de-asserts the ground signal (grounds the ground signal) in response to a first edge of the memory clock and asserts the ground signal (charges the ground signal to a power supply voltage) in response to a second edge of the memory clock.

In one embodiment, the ground signal generator may comprise an inverter that inverts the memory clock to generate the ground signal. In such an embodiment, the ground signal will thus be de-asserted after a rising edge of the memory clock and asserted after a falling edge of the memory clock. If the ground signal is pulled low after the rising edge of the memory clock while the decoded signal is asserted (charged to a power supply voltage), the first switch thus turns on to couple the ground signal to the latch. The latch latches the ground signal and is eventually reset through a feedback circuit. Thus, the latch is set and reset in a clock cycle as is known in the pulse latch arts. But unlike conventional pulse latches, the disclosed pulse latch does not block the decoding circuit from pulling the decoded signal high using a global reset signal. Instead, this blocking is performed responsive to the memory clock edge. In particular, a hold signal is generated responsive to a triggering edge of the memory clock. The hold signal blocks the decoding circuit from pulling the decoded signal high until a subsequent second clock edge. For example, if the triggering clock edge is a rising edge, the hold signal blocking would be effective until the subsequent falling edge of the clock.

The blocking of the decoding circuit from asserting the decoded signal is desirable because the address signals change from memory clock cycle to memory clock cycle. In that regard, it could be the case that the pulse latch was not selected (the address bits select for a different word line) in a current memory clock cycle. The decoded signal would thus not be asserted in that current memory clock cycle but there is the possibility that the address signals in a subsequent memory clock cycle would select for the pulse latch. If so, the decoded signal would be asserted sometime during the current memory clock cycle because the address signals need to be presented to the decoder and stable prior to the clock edge in the subsequent memory clock cycle. The asserted decoded signal could then be latched and trigger an undesirable assertion of the word line in the current memory clock cycle, leading to erroneous read or write operations. To guard against this, it is conventional to block the decoding circuit from asserting the decoded signal responsive to a global reset signal. In contrast, the disclosed pulse latch includes a reset logic circuit that is configured to control a second switch coupled between the decoded signal node and ground. The reset logic circuit controls the second switch to close if the ground signal is de-asserted while the decoded signal is de-asserted. Similarly, the reset logic circuit controls a third switch to open so as to decouple power to an inverter driving the decoded signal node if the ground signal is de-asserted with the decoded signal is de-asserted. Since the de-assertion of the ground signal is responsive to the triggering edge of the memory clock, the blocking of the decoding circuit is also edge-triggered. The disclosed pulse latch may thus also be denoted as an edge-triggered pulse latch, which leads to greatly enhanced operating speeds as compared to conventional global-reset-signal-triggered pulse latches. These and other advantages may be better understood with regard to the detailed description below.

### BRIEF DESCRIPTION OF THE DRAWINGS

FIG. 1 is a circuit diagram of a conventional pulse latch.

FIG. 2 is a timing diagram for signals in the pulse latch of FIG. 1.

FIG. 3 is a circuit diagram of a pulse latch in accordance with an embodiment of the disclosure.

FIG. 4A is a timing diagram for signals in the pulse latch of FIG. 3 in a clock cycle in which the pulse latch is not selected.

FIG. 4B is a timing diagram for signals in the pulse latch of FIG. 3 in a clock cycle in which the pulse latch is selected.

FIG. 5 is a flowchart for an example method of operation for a pulse latch in accordance with an embodiment of the disclosure.

### DETAILED DESCRIPTION

A pulse latch is provided that does not require the address signals to be held constant until the assertion of a global reset signal. In contrast, it is conventional to hold the address signals constant prior to the assertion of a global reset signal. When asserted, the global reset signal blocks the decoding circuit from changing the decoded signal responsive to changes in the address signals. After the global reset signal is asserted, new address signals may be presented to the decoding circuit because the new address signals are blocked from changing the decoded signal by the assertion of the global reset signal. But this delay in presenting new address signals until the global reset signal has been asserted slows conventional memory operation.

In contrast, the disclosed pulse latch blocks the decoding circuit responsive to a triggering memory clock edge. The following discussion is directed to embodiments in which the triggering memory clock edge is a rising edge but it will be appreciated that alternative embodiments may using the falling edge as the triggering edge of the memory clock. The triggering edge of the memory clock also causes a de-assertion (pulling low) of a ground signal. A reset logic circuit performs the blocking by asserting a hold signal responsive to the ground signal and the decoded signal. If both the ground signal and the decoded signal are low (de-asserted), the reset logic circuit blocks the decoding circuit by asserting the hold signal. Since the ground signal is an inverted version of the memory clock signal, it will always be asserted high during the low half-cycle of each memory clock cycle. The reset logic circuit de-asserts the hold signal whenever the ground signal and/or the decoded signal is asserted. Since the ground signal will always be asserted following the falling edge of the memory clock (in embodiments in which the triggering edge is a rising edge), the hold signal will always be de-asserted accordingly. The decoding circuit is then free to change the decoded signal according to the address signals for the subsequent memory clock cycle.

Note that the blocking of the decoding circuit is directed to the possibility that the decoded signal may be de-asserted in a given memory clock cycle but will be asserted in the subsequent memory clock cycle. There is no need for blocking if the decoded signal is already high in a given memory clock cycle because no erroneous assertion or de-assertion of the word line voltage will occur in that case. But it is possible that an erroneous assertion of the word line voltage may occur in a given memory cycle if the address signal did not select for the pulse latch in the current memory cycle. As discussed with regard to conventional pulse latch 100, the address signals for the disclosed pulse latch are changed from memory clock cycle to memory clock cycle. In that regard, a pulse latch is defined herein to be “selected” if prior to the triggering edge of the memory clock signal, the address signals such as A0, A1, and A2 that select for the corresponding word line are all asserted high. Conversely, if any of these address signals are low prior to the triggering edge of the memory clock, the pulse latch is deemed to be unselected.

If the pulse latch is not selected in a current memory clock cycle, the decoded signal will be de-asserted prior to the triggering edge of the memory clock. It is the triggering edge of the memory clock that will then determine the timing for the assertion of the hold signal by the reset logic circuit. For example, suppose the triggering edge is a rising edge for the memory clock. The ground signal will thus be de-asserted at the rising edge of the memory clock. If the decoded signal were already de-asserted, the reset logic circuit will assert the hold signal responsive to the de-assertion of the ground signal, which in turn is responsive to the rising edge of the clock. The blocking of the decoding circuit by the hold signal is thus responsive to the triggering clock edge rather than to a global reset signal. This is quite advantageous because the address signals may change responsive to the assertion of the hold signal (and hence responsive to the triggering clock edge). The frequency of the memory clock may thus be increased because the decoding circuit has more time to decode the newly-changed address signals. In contrast, prior-art memory clock speeds needed to account for the “dead time” during which the address signals could not change until the assertion of the global reset signal. It was only after the asserted global reset signal was blocking the decoding circuit from changing the decoded signal that a conventional memory could safely present new address signals to the decoding circuit. In contrast, the memory including the edge-triggered pulse latch disclosed herein may present the address signals for a subsequent memory cycle sooner in a current memory cycle because there is no delay needed to account for any global reset signal assertion.

The decoded signal from the decoding circuit may also be denoted as the DEC signal that is carried on a DEC signal node. The decoding circuit includes a decoding circuit inverter that drives the DEC signal onto the DEC signal node. Regardless of whether it is asserted or not in a current memory clock cycle, the DEC signal may change after a current memory clock cycle edge in anticipation of the next memory cycle. Should the pulse latch not be selected in both the current memory cycle and the subsequent memory cycle, the DEC signal will remain low in the transition from the current memory cycle into the next memory cycle. But it might be the case that the pulse latch was not selected in the current memory cycle but will be selected in the subsequent memory cycle. In such as case, the DEC signal will switch from low to high after the rising edge of the memory clock in the current memory cycle and prior to the rising edge of the subsequent memory clock cycle.

The DEC signal thus needs to transition to whatever state is appropriate for the subsequent memory clock cycle sometime after the rising edge in the current memory clock cycle. There is hence the possibility of the following scenario: the pulse latch was not selected in the current memory cycle but will be in the subsequent memory cycle such that the DEC signal goes from low to high sometime after the rising edge of the current memory clock cycle. The pulse latch could then latch the low state of the ground signal (VSSG) and undesirably trigger an assertion of the word line voltage despite the pulse latch not being selected to do so in the current memory clock cycle. The undesired assertion of the word line would then lead to write or read errors.

To block the decoding circuit from undesirably asserting the DEC signal, the reset logic circuit advantageously controls a ground switch between the DEC signal node and ground. The reset logic circuit switches the ground switch on in response to the rising edge of the memory clock to ground the DEC signal node if the pulse latch is not selected in the current memory clock cycle. In addition, the reset logic switch controls a power switch between a power supply node and the decoding circuit inverter driving the DEC signal node. The reset logic circuit switches the power switch off in response to the rising edge of the memory if the pulse latch is not selected in the current memory cycle. In other words, if both the DEC signal and the ground signal VSSG are low, the reset logic circuit guards against the DEC signal subsequently transitioning high by turning the ground switch on to ground the DEC signal node. At the same time, the reset logic circuit turns off the power switch to prevent the decoding circuit inverter from fighting with the ground switch by subsequently attempting to recharge the DEC signal node. The address signals may thus transition safely into their new state for the subsequent memory clock cycle prior to the rising edge of the subsequent memory clock cycle.

The reset logic circuit controls the ground switch to remain open (allowing the DEC signal node to float) if the VSSG signal and/or the DEC signal is high. Similarly, the reset logic switch controls the power switch to stay on if the VSSG signal and/or the DEC signal is high. In that regard, the VSSG signal is driven high in response to a falling edge of the memory clock cycle. Thus, regardless of whether the DEC signal node was grounded subsequent to the rising edge of the memory clock, it will always be floating (with respect to the switch controlled by the reset logic circuit) subsequent to the falling edge of the memory clock. Similarly, the decoding circuit inverter driving the DEC signal node will also be powered on subsequent to the falling edge of the memory clock regardless of the state of the DEC signal. In this fashion, the DEC signal node may respond to the decoding of the subsequent memory cycle's address bits and be driven high (if the pulse latch is selected in this subsequent memory cycle) prior to the rising edge of the memory clock.

The blocking of the decoding circuit is thus triggered by the clock edge. This is in sharp contrast to the operation of conventional pulse latch 100 in which the DEC signal node reset was triggered by the global reset signal. As discussed earlier, the global reset signal was asserted only after allowing for the delay required to pull the word line voltage high. But the disclosed pulse latch advantageously may reset the DEC signal node in response to the triggering edge of the memory clock as opposed to any reaction in the word line voltage. The presentation of the address signals to the address decoder for the next memory clock cycle may thus be accomplished subsequent to the triggering clock edge instead of subsequent to the assertion of the global reset signal. In this fashion, the memory clock frequency may be advantageously increased, which results in faster memory read and write operations. These and other advantages may be better appreciated with regard to the following example embodiments.

### Example Embodiments

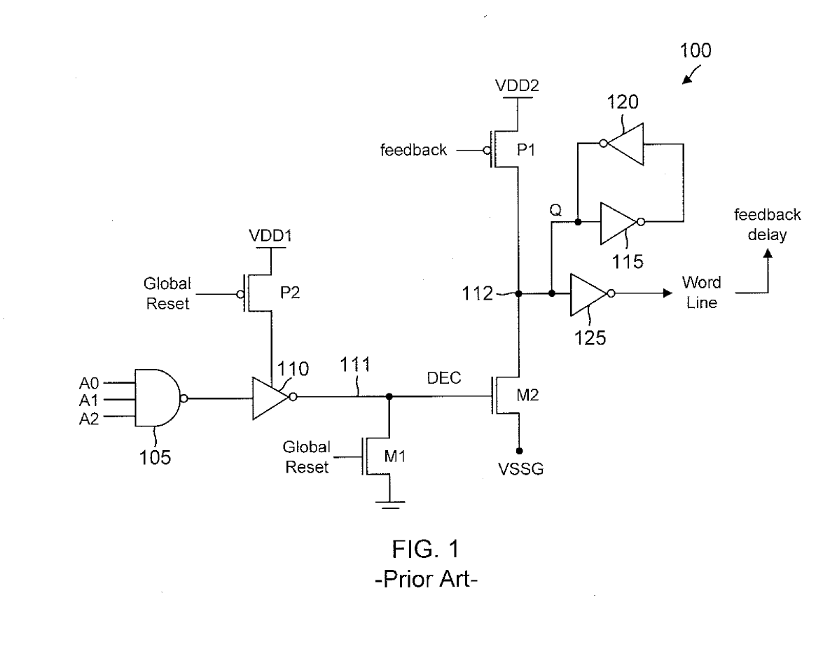

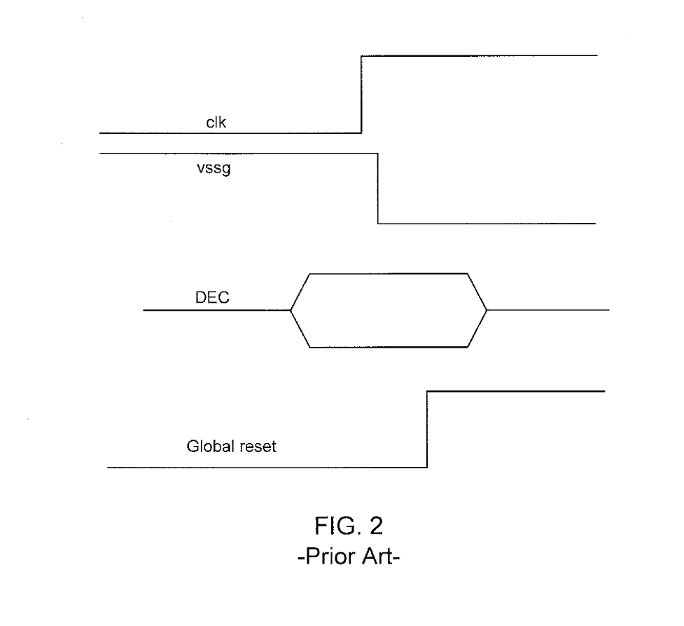

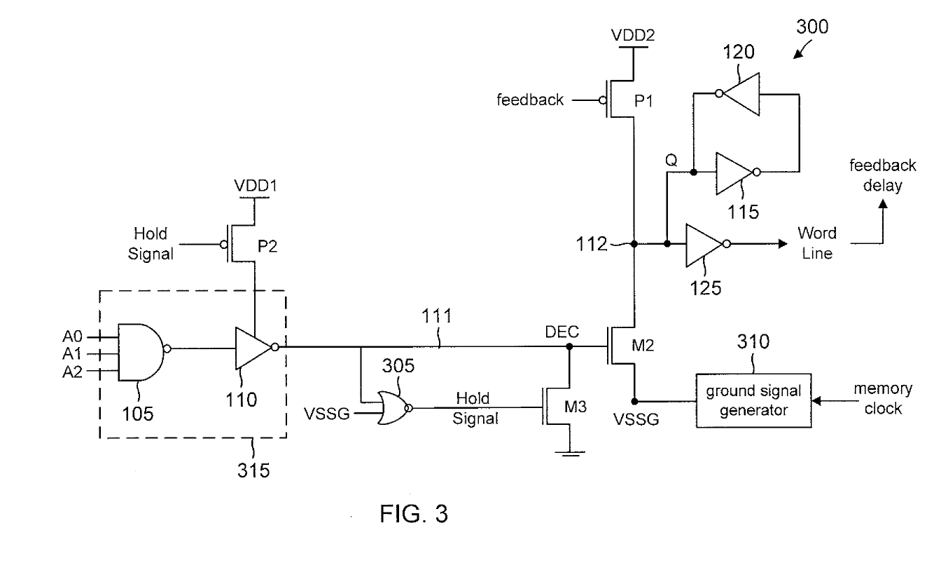

An example pulse latch 300 is shown in FIG. 3. Note that the operation of pulse latch 300 with regard to the latched Q signal, transistor M2, the VSSG signal, cross-coupled latches 115 and 120, inverter 125, the word line, the feedback delay signal generation, and transistor P1 occurs as discussed with regard to pulse latch 100 of FIG. 1. This operation will thus be reviewed again for completeness. There are three address bits A0, A1, and A2 being decoded through a NAND gate 105. The number of address bits may of course be varied in alternative embodiments. NAND gate 105 decodes the address bits and drives an inverter 110 accordingly. Inverter 110 inverts the decoded NAND output signal into a decoded (DEC) signal carried on a DEC signal node 111. The combination of NAND gate 105 and inverter 110 may be designated as a decoding circuit 315. Decoding circuit 315 either asserts or de-asserts the DEC signal responsive to the state of the address signals.

The DEC signal controls the state of a first switch that may close to couple a ground signal VSSG to a latch. For example, the first switch may comprise an NMOS transistor M2 that has its gate coupled to DEC signal node 111. Thus, when all the address bits are true (asserted high), the DEC signal is asserted so as to switch on NMOS transistor M2. A source of M2 is coupled to a VSSG signal (the ground signal) generated by a ground signal generator 310 responsive to the memory clock. In one embodiment, ground signal generator 310 may comprise an inverter such that the VSSG signal is pulled low in response to rising edges of the memory clock and pulled high in response to falling edges of the memory clock. A drain 112 for transistor M2 is coupled to an input of an inverter 115 that is cross-coupled with another inverter 120 to form the storage unit in pulse latch 300. Thus, when the DEC signal is asserted, drain 112 of M2 is pulled to ground and latched within the storage unit formed by cross-coupled inverters 120 and 115.

The voltage for drain 112 of transistor M2 is designated as a latched signal Q since this signal is latched in pulse latch 300. The result of the DEC signal being asserted from the decoding of the address bits is that pulse latch 300 latches the binary low state of the Q signal. An inverter 125 inverts the latched Q signal to drive a word line (not illustrated). Thus, when the DEC signal is asserted and the VSSG signal grounded, the word line voltage is driven high to a power supply voltage VDD2. As discussed earlier, a feedback circuit (not illustrated) detects the assertion of the word line voltage and asserts a feedback signal to reset pulse latch 300. For example, a PMOS transistor P1 may be coupled between drain 112 and a power supply node supplying the power supply voltage VDD2 and have its gate driven by the feedback signal. The feedback signal is asserted low to switch P1 on such that the Q signal is driven high and latched in pulse latch 300. The word line voltage is then driven low accordingly through inverter 125. It may readily be appreciated why pulse latch 300 is denoted as a “pulse” latch since it is used to momentarily pulse the word line voltage high in response to the address signal decoding so as to access memory cells coupled to the word line.

A reset logic circuit such a NOR gate 305 processes the DEC signal with the VSSG signal to produce a hold signal that blocks decoding circuit 315 from asserting the DEC signal. The reset logic circuit controls the state of a ground switch such as an NMOS transistor M3 coupled between DEC signal node 111 and ground and having its gate driven by the hold signal. Thus, when the hold signal is driven high, the DEC signal will be reset low.

The hold signal also controls a power switch such as a PMOS transistor P2 that supplies power to decoding circuit inverter 110. The source of P2 couples to a power supply node supplying a power supply voltage VDD1 that may be lower than the power supply voltage VDD2 driving the word line. The drain of P2 couples to a power terminal for decoding circuit inverter 110. When the hold signal is asserted, P2 thus shuts off so as to disconnect decoding circuit inverter 110 from the power supply node carrying power supply voltage VDD1. Decoding circuit 315 is thus blocked from asserting the DEC signal while the hold signal is asserted.

Because of the NORing of the DEC signal with the VSSG signal to produce the hold signal, the grounding of the DEC signal through the switching on of transistor M3 as well as the blocking of decoding circuit 315 through the switching off of transistor P2 depends upon whether the pulse latch is selected or not. As discussed earlier, pulse latch 300 is deemed to be “selected” if prior to the rising edge of the memory clock signal, the address signals such as A0, A1, and A2 that select for the corresponding word line are all asserted high. As also discussed earlier, the memory clock signal controls the low state (de-assertion) of the VSSG signal through ground signal generator 310. In particular, the VSSG signal is pulled low to ground in response to the rising edge of the memory clock signal. The DEC signal will be setup either high or low and held prior to the rising edge of the memory clock signal. If the DEC signal is asserted high in this fashion to the power supply voltage VDD1 prior to the rising edge of the memory clock, NOR gate 305 does not respond to the VSSG signal being pulled low. In other words, the hold signal will remain low despite the VSSG signal being pulled low in response to the rising edge of the memory clock. Conversely, if the DEC signal were asserted low prior to the rising edge of the memory clock, NOR gate 305 will assert the hold signal to the power supply voltage VDD1 in response to the VSSG signal going low. As discussed earlier, pulse latch 300 is deemed to be “unselected” if prior to the rising edge of the memory clock signal, the address signals such as A0, A1, and A2 that select for the corresponding word line are not all asserted high. In one embodiment, NOR gate 305 and transistor M1 may be deemed to comprise a means for grounding the decoded signal node 111 responsive to the both the ground signal VSSG and the decoded signal DEC being de-asserted.

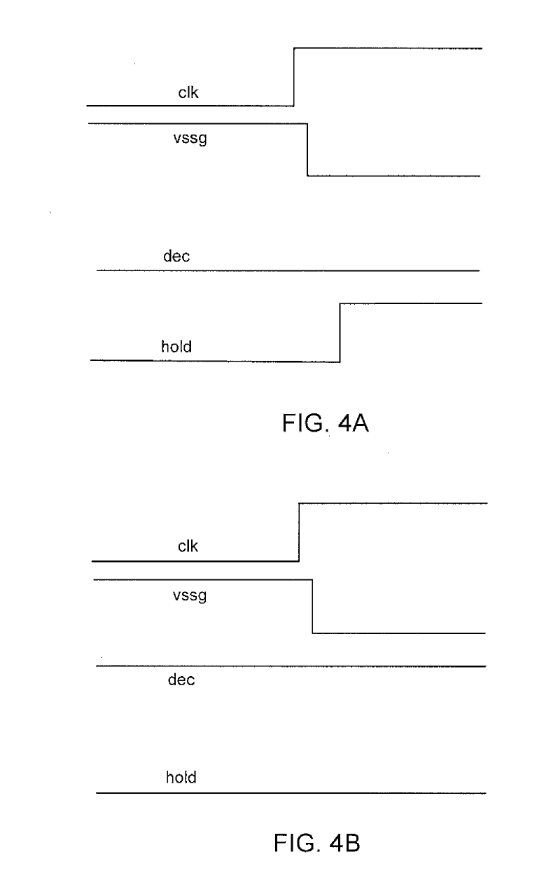

The operation of NOR gate 305 may be better understood with regard to the timing diagrams of FIGS. 4A and 4B. The timing diagram of FIG. 4A corresponds to the DEC signal being low (the pulse latch being unselected) prior to the triggering edge of the memory clock signal, which in this embodiment is the rising edge. The VSSG signal goes low in response to this rising edge but cannot affect the latched Q signal (discussed with regard to FIG. 3) should the DEC signal subsequently transition high in preparation for a subsequent memory clock cycle because the hold signal is driven high in response to VSSG going low. The DEC signal will thus be maintained low through the resulting connection of DEC signal node 111 to ground through transistor M3 in response to transistor M3 being turned on from the assertion of the hold signal. Similarly, the switching off of transistor P2 responsive to the assertion of the hold signal blocks decoding circuit 315 from asserting the DEC signal while the hold signal is asserted. This is advantageous since the address signals may be changing state in preparation for the next memory clock cycle. Should the address signals for the subsequent memory clock cycle all be asserted high after the rising edge in a current memory clock cycle, the DEC signal could be driven high in the current memory clock cycle, which may affect the state of the latched Q signal undesirably. But the assertion of the hold signal protects the latched Q signal from responding to any change of the address signals in the current memory clock cycle if the DEC signal was low prior to the rising edge of the memory clock.

In contrast, the timing diagram of FIG. 4B corresponds to the DEC signal being high prior to the rising edge of the memory clock. The VSSG signal is then pulled low to ground accordingly. But NOR gate 305 cannot respond to this low state for the VSSG signal since the DEC signal is high. The hold signal is then maintained low at ground, which prevents transistor M3 from pulling the DEC signal low. This is quite advantageous as the hold time (not illustrated) for the DEC signal need not account for any global reset generation circuit delay. It will be appreciated that the address signals may be held for some period (not illustrated) after the rising edge of the memory clock so that the hold signal may either be asserted or not asserted depending upon whether the DEC signal were low (FIG. 4A) or high (FIG. 3B). In other words, NOR gate 305 requires some time to decode its input signals and drive the ground switch and the power switch accordingly. But this delay may be simulated and accounted for—it may then be optimized without also having to account for the delay discussed earlier with regard to conventional reset signal generation. In contrast, the delay of the conventional reset signal generation is much greater. Memory operation speed may thus be increased accordingly. In that regard, pulse latch 300 may be designated as an “edge-triggered” pulse latch in that the blocking of the decoding circuit is responsive to a memory clock edge. An example method of operation for pulse latch 300 will now be discussed.

### Example Method of Operation

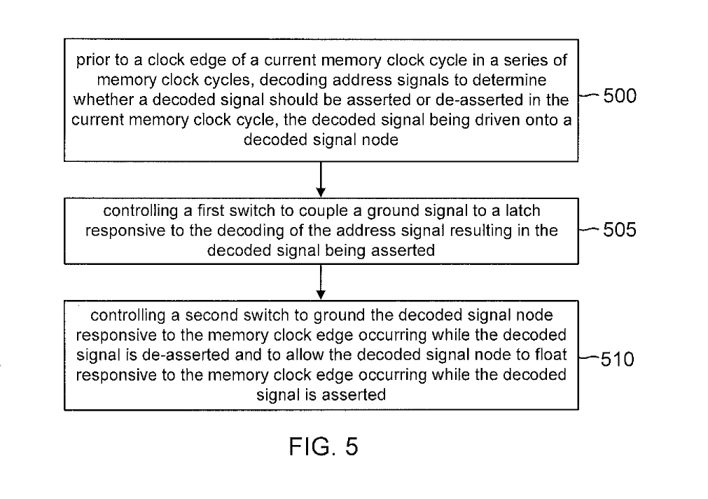

Turning now to FIG. 5, a flowchart for an example method of operation is provided. The method begins with an act 500 of, prior to a clock edge of a current memory clock cycle in a series of memory clock cycles, decoding address signals to determine whether a decoded signal should be asserted or de-asserted in the current memory clock cycle, the decoded signal being driven onto a decoded signal node. Such an act is generic to whatever triggering clock edge (rising or falling edge) is used by the ground signal generator to de-assert and thus ground the ground signal. The decoding of the address signals in a current memory clock cycle should be performed prior to the triggering clock edge so that the pulse latch may latch the ground signal if the first switch (M2) is switched on by the decoded signal being asserted.

The method continues with an act 505 of controlling a first switch to couple a ground signal to a latch responsive to the decoded signal being asserted from the decoding of the address signals. An example of such a first switch is transistor M2 in pulse latch 300.

Finally, the method continues with an act 310 of controlling a second switch to ground the decoded signal node responsive to the memory clock edge occurring while the decoded signal is de-asserted and to allow the decoded signal node to float responsive to the memory clock edge occurring while the decoded signal is asserted. An example of such control is NAND gate 305 asserting the hold signal to turn on transistor M3 to ground decoded signal node 111 in response to the VSSG signal being de-asserted while the decoded signal is de-asserted. Similarly, NAND gate 305 does not assert the hold signal if the DEC signal was already asserted prior to the de-assertion of the VSSG signal.

As those of ordinary skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A pulse latch, comprising:
a decoding circuit configured to decode address signals to determine whether a decoded signal carried on a decoded signal node is asserted or de-asserted in a current cycle of a memory clock;
a ground signal generator configured to generate a ground signal such that the ground signal is de-asserted in response to a first edge of the memory clock and asserted in response to a second edge of the memory clock;
a first switch operable to couple the ground signal to a latch responsive to the decoded signal being asserted;
a second switch coupled between the decoded signal node and ground; and
a reset logic circuit configured to control the second switch to close responsive to both the ground signal and the decoded signal being de-asserted and to control the second switch to open responsive to the ground signal and/or the decoded signal being asserted.

2. The pulse latch of claim 1, wherein the decoding circuit includes an inverter for driving the decoded signal onto the decoded signal node, the pulse latch further comprising a third switch coupled between the inverter and a power supply node, and wherein the reset logic circuit is further configured to control the third switch to open responsive to both the ground signal and the decoded signal being de-asserted so as to decouple the inverter from the power supply node and to control the second switch to close responsive to the ground signal and/or the decoded signal being asserted so as to couple the inverter to the power supply node.

3. The pulse latch of claim 2, wherein the decoding logic circuit further comprises a NAND gate configured to process the address signals to provide an output signal to the inverter.

4. The pulse latch of claim 1, wherein the ground signal generator comprises an inverter configured to invert the memory clock to produce the ground signal.

5. The pulse latch of claim 1, wherein the first switch comprises an NMOS transistor, the pulse latch further comprising a pair of cross-coupled inverters configured to latch a voltage state for a drain of the NMOS transistor.

6. The pulse latch of claim 5, further comprising an inverter configured to invert the voltage state for the drain into an inverted voltage and drive a word line with the inverted voltage.

7. The pulse latch of claim 6, wherein the word line is an SRAM word line.

8. The pulse latch of claim 2, wherein the second switch comprises an NMOS transistor having a source coupled to ground and a drain coupled to the decoded signal node, and wherein the third switch comprises a PMOS transistor.

9. The pulse latch of claim 6, further comprising a PMOS transistor having a source coupled to a power supply node and a drain coupled to the drain of the NMOS transistor, and wherein the PMOS transistor is configured to switch on responsive to the word line voltage being asserted.

10. A method, comprising:
prior to a clock edge of a current memory clock cycle in a series of memory clock cycles, decoding address signals to determine whether a decoded signal should be asserted or de-asserted in the current memory clock cycle, the decoded signal being driven onto a decoded signal node;
controlling a first switch to couple a ground signal to a latch responsive to the decoded signal being asserted from the decoding of the address signals; and
controlling a second switch to ground the decoded signal node responsive to the memory clock edge occurring while the decoded signal is de-asserted and to allow the decoded signal node to float responsive to the memory clock edge occurring while the decoded signal is asserted.

11. The method of claim 10, wherein decoding the address signals comprises NANDing the address signals to produce a NAND signal.

12. The method of claim 11, wherein decoding the address signals further comprises inverting the NAND signal to produce the decoded signal.

13. The method of claim 10, further comprising inverting the memory clock to produce the ground signal.

14. The method of claim 10, wherein controlling the first switch comprises controlling an NMOS transistor.

15. The method of claim 10, wherein controlling the second switch comprises controlling an NMOS transistor.

16. The method of claim 15, wherein controlling the NMOS transistor comprises NORing the decoded signal with the ground signal to produce a hold signal that drives a gate of the NMOS transistor.

17. The method of claim 10, further comprising inverting a latched signal in the latch to assert a word line voltage; and sensing the assertion of the word line voltage to reset the latch.

18. A circuit, comprising:
a decoding circuit configured to decode address signals to determine whether a decoded signal carried on a decoded signal node is asserted or de-asserted in a current cycle of a clock;
a ground signal generator configured to assert a ground signal responsive to a first edge of the clock and to de-assert the ground signal responsive to a second edge of the clock;
a latch;
a first switch configured to couple the ground signal to the latch when the decoded signal is asserted; and
means for grounding the decoded signal node responsive to both the ground signal and the decoded signal being de-asserted.

19. The circuit of claim 18, wherein the means comprises:
a second switch coupled between the decoded signal node and ground; and
a reset logic circuit configured to control the second switch responsive to the decoded signal and the ground signal.

20. The circuit of claim 19, wherein the reset logic circuit comprises a NOR gate, and wherein the NOR gate is configured to decouple an inverter in the decoding circuit from a power supply node responsive to both the ground signal and the decoded signal being de-asserted.
